(19) United States
(12) Patent Application Publication
(10) Pub. No.: US 2026/0090414 A1
(43) Pub. Date: Mar. 26, 2026

(54) ADHERED SAP SUBSTRATE FOR CuBOL ASSEMBLY PACKAGE

(71) Applicant: QUALCOMM Incorporated, San Diego, CA (US)

(72) Inventors: Hyun-Il MOON, Suwon-si (KR); Kuiwon KANG, San Diego, CA (US); Joan Rey Villarba BUOT, Escondido, CA (US); Hong Bok WE, San Diego, CA (US)

(21) Appl. No.: 18/892,171

(22) Filed: Sep. 20, 2024

(51) Int. Cl. H01L 23/498; H01L 21/48

(52) U.S. Cl. CPC H10W 70/65; H10W 70/05

(57) ABSTRACT

Disclosed are semiconductor packages. A semiconductor package may include a dielectric layer and a solder resist (SR) on the dielectric layer. The solder resist may define a first SR area, a second SR area, and a trench open area between the first SR area and the second SR area. An upper surface of the dielectric layer may be covered with the SR in the first SR area and the second SR area, and not covered in the trench open area. One or more traces may be formed on the upper surface of the dielectric layer within the trench open area. At least one trace may comprise an anchor. The anchor may strengthen adherence of the trace to the dielectric such that trace lift is mitigated or prevented altogether.

### BACKGROUND OF THE DISCLOSURE

### 1. Field of the Disclosure

This disclosure relates generally to die packages or modules, and more specifically, but not exclusively, to semiconductor packages/modules that include adhered semi-additive process (SAP) substrate for copper BOL (CuBOL) assembly package and fabrication techniques thereof.

### 2. Description of the Related Art

In semiconductor packages such as CuBOL packages, open shorts fails have often been encountered, e.g., due to SAP substrate trace peel-off. Trace peel-off risks are present at trench open SR area, which are usually caused by mechanical stress from lower adhesion between Cu trace bottom to dielectric surface. Accordingly, there is a need for systems, apparatus, and methods that overcome the deficiencies of conventional semiconductor packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor package is disclosed. The semiconductor package may comprise a dielectric layer. The semiconductor package may also comprise a solder resist (SR) on the dielectric layer. The SR may define a first SR area, a second SR area, and a trench open area between the first SR area and the second SR area. An upper surface of the dielectric layer may be covered with the SR in the first SR area and the second SR area, and may not be covered in the trench open area. The semiconductor package may further comprise one or more traces on the upper surface of the dielectric layer within the trench open area. At least one trace of the one or more traces may comprise an anchor on a lower surface thereof. The anchor may penetrate the upper surface of the dielectric layer to a depth below the upper surface of the dielectric layer.

A method of fabricating a semiconductor package is disclosed. The method may comprise providing a dielectric layer. The method may also comprise forming a solder resist (SR) on the dielectric layer. The SR may define a first SR area, a second SR area, and a trench open area between the first SR area and the second SR area. An upper surface of the dielectric layer may be covered with the SR in the first SR area and the second SR area, and may not be covered in the trench open area. The method may further comprise forming one or more traces on the upper surface of the dielectric layer within the trench open area. At least one trace of the one or more traces may comprise an anchor on a lower surface thereof. The anchor may penetrate the upper surface of the dielectric layer to a depth below the upper surface of the dielectric layer.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A illustrates a top view of a conventional semiconductor package.

FIG. 1B illustrates zoomed in portion of the top view of the conventional semiconductor package of FIG. 1A.

FIG. 1C illustrates a cross-sectional view within a trench open area of the conventional semiconductor package.

FIG. 1D illustrates the same cross-sectional view within the trench open area in which the conventional semiconductor package is under external stress.

FIG. 1E illustrates design rule dimensions of the trench open area of the conventional semiconductor package.

FIG. 2A illustrates a top view of a semiconductor package in accordance with one or more aspects of the disclosure.

FIG. 2B illustrates a cross-sectional view within a trench open area of the semiconductor package in accordance with one or more aspects of the disclosure.

FIG. 2C illustrates the same cross-sectional view within the trench open area in which the semiconductor package in accordance with one or more aspects of the disclosure is under external stress.

FIG. 2D illustrates design rule dimensions of the trench open area of the semiconductor package in accordance with one or more aspects of the disclosure.

FIG. 3A-3H illustrate examples of stages of fabricating a semiconductor package in accordance with one or more aspects of the disclosure.

FIG. 4A-4D illustrates examples of shapes of scribe lines and anchors of a semiconductor package in accordance with one or more aspects of the disclosure.

FIG. 5-7 illustrate flow charts of example methods of manufacturing a semiconductor package in accordance with at one or more aspects of the disclosure.

FIG. 8 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor packages and methods for fabricating the same. In an aspect, the semiconductor package may comprise a dielectric layer. The semiconductor package may also comprise a solder resist (SR) on the dielectric layer. The SR may define a first SR area, a second SR area, and a trench open area between the first SR area and the second SR area. An upper surface of the dielectric layer may be covered with the SR in the first SR area and the second SR area, and may not be covered in the trench open area. The semiconductor package may further comprise one or more traces on the upper surface of the dielectric layer within the trench open area. At least one trace of the one or more traces may comprise an anchor on a lower surface thereof. The anchor may penetrate the upper surface of the dielectric layer to a depth below the upper surface of the dielectric layer. In this way, trace lifts may be mitigated or even prevented altogether.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

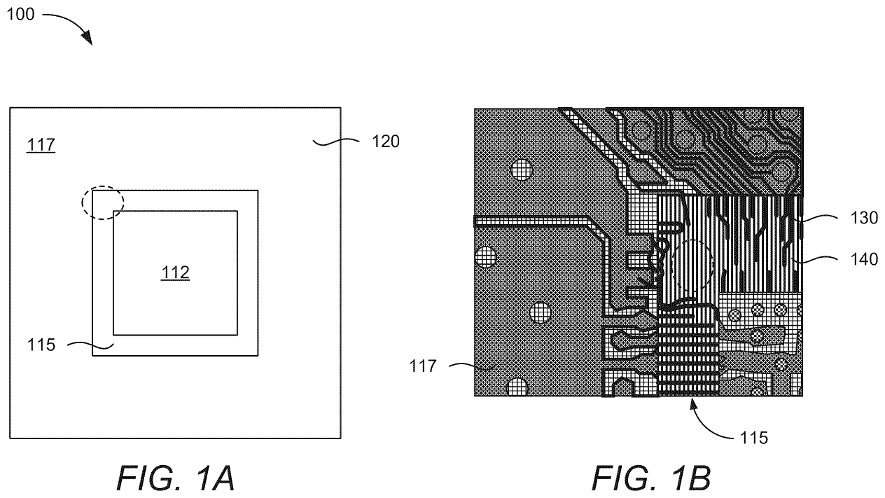

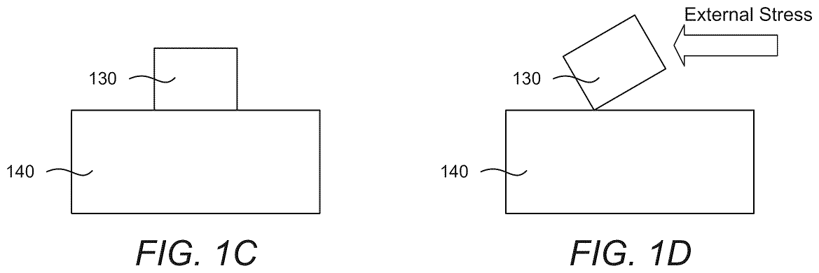

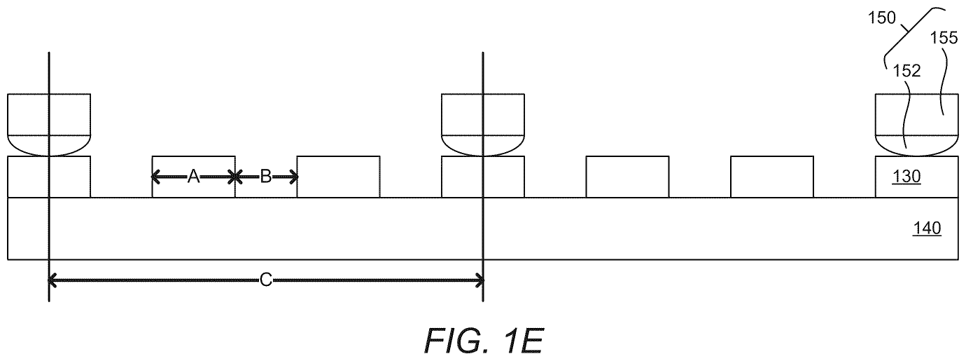

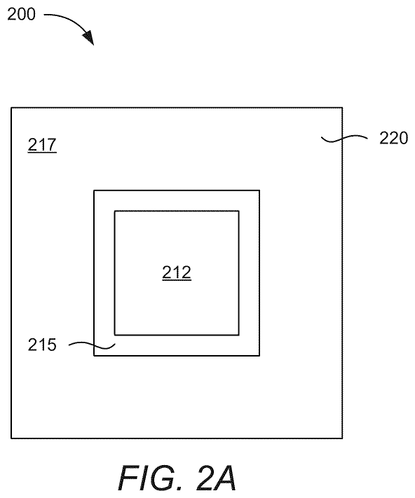

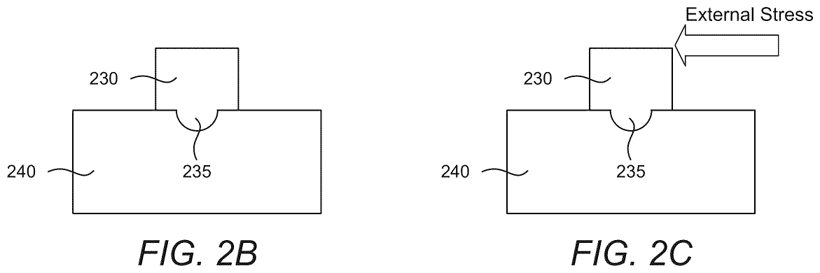

As indicated above, in semiconductor packages such as CuBOL packages, open shorts fails have often been encountered, e.g., due to SAP substrate trace peel-off, also referred to as trace lift. Trace peel-off risks are present at trench open area, which are usually caused by mechanical stress from lower adhesion between Cu trace bottom to dielectric surface. FIG. 1A illustrates a top view of a conventional semiconductor package. As seen, the conventional semiconductor package 100 in which three areas are defined—an interior (or chip) area 112, an exterior area 117, and a trench open area 115 in between the interior and exterior areas 112, 117. A solder resist (SR) 120 covers the interior and exterior areas 112, 117, but does not cover the trench open area 115.

More details of the portion of the conventional semiconductor package 100 of FIG. 1A highlighted by a dashed oval is illustrated in FIG. 1B. As seen, the SR 120 covers the dielectric layer 140 of the interior and exterior areas 112, 117, but does not cover the dielectric layer 140 of trench open area 115. Within the trench open area 115, the conventional semiconductor package 100 includes traces 130, which are conductive and electrically couple contacts within the semiconductor package 100.

However, note that in the dashed oval area of FIG. 1B, the traces 130 have been peeled off. That is, trace lifts have occurred, possibly due to external stresses. This is illustrated in FIGS. 1C and 1D providing a cross-sectional view within the trench open area 115 of the semiconductor package 100. In FIG. 1C, it is seen that the trace 130 is formed on the dielectric layer 140. But as seen in FIG. 1D, due to external stress, the trace 130 may be peeled or otherwise lifted. This can cause failures such as shorts.

Also, process to fabricate the conventional semiconductor package may be improved. For context, dimensions associated with trench open area design rule for the conventional semiconductor package is seen in FIG. 1E. As seen, the conventional semiconductor package 100 is illustrated as also comprising a plurality of contact structures 150. Each contact structure 150 includes a bump 152 and a bump pad 155 on the bump 152.

In FIG. 1E, the trench open area design rule specifies ‘A’, ‘B’, and ‘C’ dimensions which are minimum trench width, minimum trace space (between adjacent traces 130), and minimum bump pitch (center-to-center distance between adjacent contact structures 150). For the conventional semiconductor package 100, ‘A’ can be as large as 16 μm, ‘B’ can be as large as 12 μm, and ‘C’ can be as large as 84 μm. Such large dimensions can make it difficult to minimize sizes of conventional semiconductor packages.

To address such issues, these and other issues (e.g., trace lifts, large sizes) of the conventional semiconductor package, it is proposed to provide extra adherence mechanisms to mitigate or even prevent trace lifts from occurring. Also by providing additional adherence mechanisms, the design rules can be tightened to reduce the size.

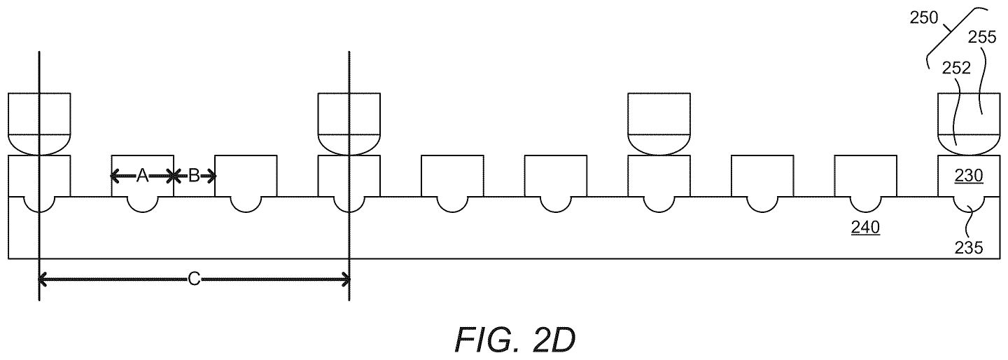

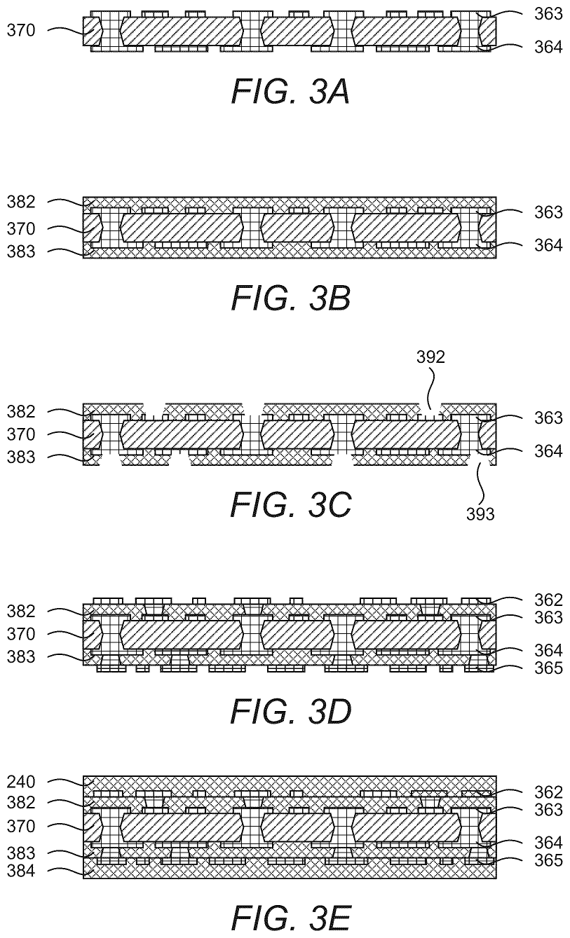

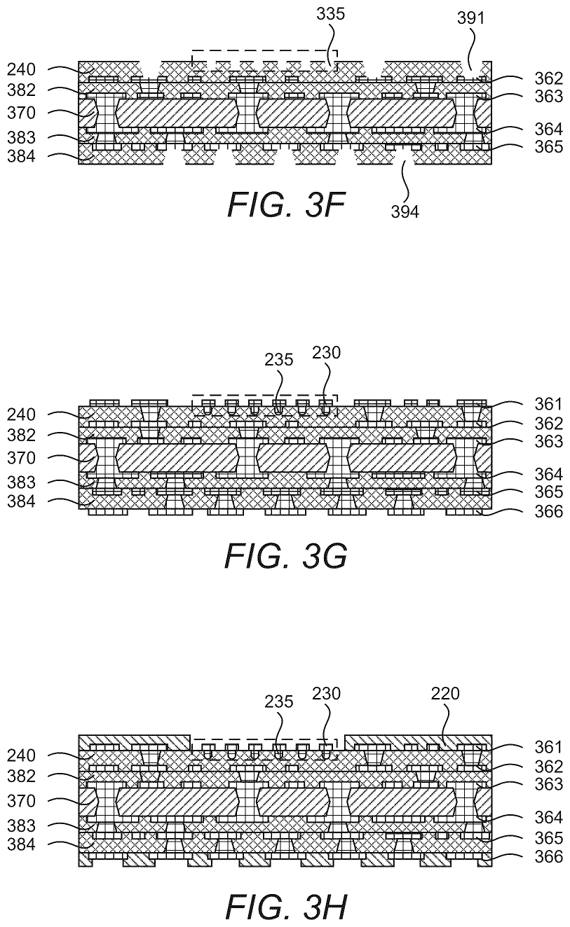

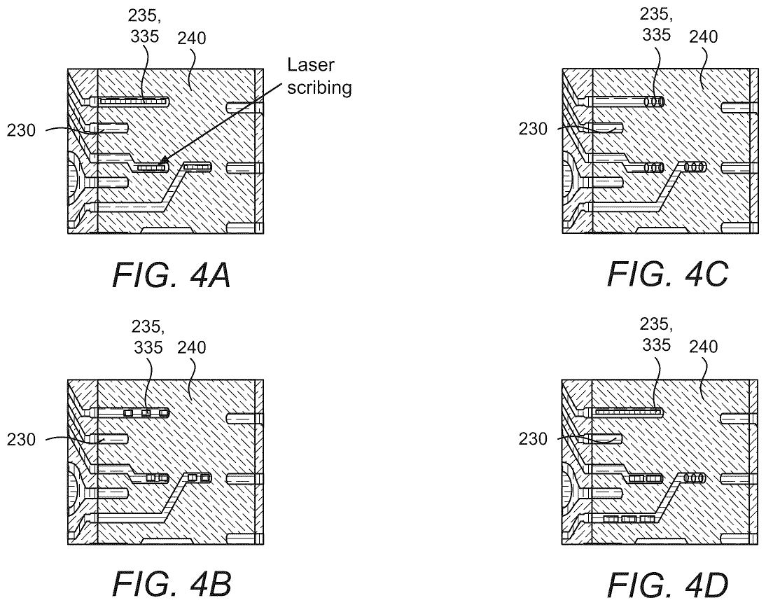

FIG. 2A illustrates a top view of a semiconductor package 200 in accordance with one or more aspects of the disclosure. The semiconductor package 200 may include a solder resist (SR) 220 on a dielectric layer 240 (not seen in FIG. 2A). The SR 220 may define a first SR area 212 (e.g., an interior or chip area), a second SR area 217 (e.g., an exterior area), and a trench open area 215 between the first SR area 212 and the second SR area 217. In an aspect, an upper surface of the dielectric layer 240 may be covered with the SR in the first SR area 212 and the second SR area 217. However, in the trench open area 215, the dielectric layer 240 may not be covered, i.e., the dielectric layer 240 may be exposed in the trench open area 215.

FIG. 2B illustrates a cross-sectional view within trench open area 215 of the semiconductor package 200 in accordance with one or more aspects of the disclosure. As seen, a trace 230 may be formed on upper surface of the dielectric layer 240 within the trench open area 215. That is, the trace 230 may be in direct contact with the upper surface of the dielectric layer 240.

Note that the trace 230 may include an anchor 235, which may be formed on lower surface of the trace 230. The presence of the anchor 235 helps to mitigate trace lift or peel off from occurring under external stress as seen in FIG. 2C.

In an aspect, the trace 230 and the anchor 235 may be integrally formed from a conductive material such as copper (Cu). In another aspect, the depth of penetration of the anchor 235 into the dielectric layer 240 may be less than a height of the dielectric layer 240. For example, the maximum penetration depth may be less than the height of the dielectric layer 240, e.g., 10 μm less. In a further aspect, a width of the anchor 235 may be less than a width of the corresponding trace 230. For example, the width of the anchor 235 may be less than or equal to half of the width of the trace 230.

In FIGS. 2B and 2C, only one trace 230 and corresponding anchor 235 are illustrated for simplicity of explanation. However, it should be noted that any number of traces 230 may be formed. That is, there can be one or more traces 230 formed within the trench open area 215 configured to electrically couple contacts within the semiconductor package 200 and/or to dies, chips, packages external to the semiconductor package 200. Corresponding anchors 235 may be formed for some or all of the one or more traces 230.

FIG. 2D illustrates design rule dimensions of the trench open area of the semiconductor package in accordance with one or more aspects of the disclosure. The presence of the anchors 235 can enable the design rules to be tightened relative to the design rules of the conventional semiconductor package design. For example, as seen in FIG. 2D, ‘A’ (minimum trench width) can be less than or equal to 8 μm and ‘B’ (minimum trace space between adjacent traces 230) can be less than or equal to 12 μm.

Also as seen in FIG. 2D, the semiconductor package 200 may include a plurality of contact structures 250, i.e., there can be at least two contact structures 250. The contact structure 250 may comprise a bump 252 and a bump pad 255. The contact structure 250 structure may be electrically coupled to a corresponding trace 230. For example, the bump 252 may be in direct contact with the corresponding trace 230. In this instance, the design rule may be such that ‘C’ (center-to-center distance between adjacent contact structures 150) can be less than or equal to 54 μm. Such reductions in the design rules (in any one or more of dimensions ‘A’, ‘B’, ‘C’) can enable reduction in the sizes of the semiconductor packages, greater functionalities (e.g., due to more connections being available), or a combination of both.

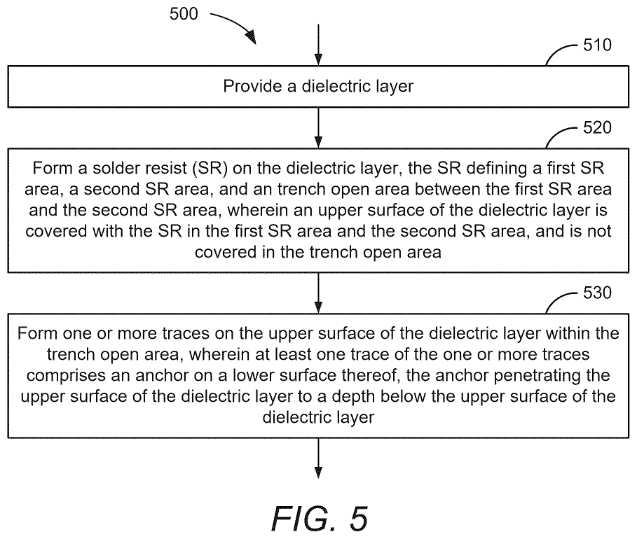

FIG. 3A-3H illustrate examples of stages of fabricating a semiconductor package—such as the semiconductor package 200—in accordance with at one or more aspects of the disclosure. Note that a semiconductor package in accordance with one or more aspects of the present disclosure can have any number of dielectric layers and any number of metal layers. However, for explanation purposes, stages of fabricating a semiconductor package with four (4) dielectric layers (two on each side of a core) and six (6) metal layers (three on each side of the core) are illustrated. The metal layers may be formed from any number of conductive metals such as copper (Cu).

FIG. 3A illustrates a stage in which conductive metal may be deposited and patterned to form third metal layer 363 (e.g., M3) and fourth metal layer 364 (e.g., M4) on a core 370. For example, the third metal layer 363 may be formed on an upper surface of the core 370, and the fourth metal layer 364 may be formed on a lower surface of the core 370. Through-core vias (not numbered) may be formed to electrically couple one or more pads of the third metal layer 363 with one or more pads of the fourth metal layer 364.

FIG. 3B illustrates a stage in which second dielectric layer 382 and third dielectric layer 383 may be formed (e.g., laminated) on the upper and lower surfaces of the core 370, respectively. The second dielectric layer 382 may cover the third metal layer 363, and the third dielectric layer 383 may cover the fourth metal layer 364.

FIG. 3C illustrates a stage in which second via holes 392 and third via holes 393 may be formed within the second dielectric layer 382 and the third dielectric layer 383, respectively. In an aspect, the second via holes 392 and/or the third via holes 393 may be formed through laser drilling. The second via holes 392 may expose one or more pads of the third metal layer 363, and the third via holes 393 may expose one or more pads of the fourth metal layer 364.

FIG. 3D illustrates a stage in which conductive metal may be deposited and patterned to form second metal layer 362 (e.g., M2) and fifth metal layer 365 (e.g., M5) on the second dielectric layer 382 and third dielectric layer 383, respectively. For example, the second metal layer 362 may be formed on an upper surface of the second dielectric layer 382, and the fifth metal layer 365 may be formed on a lower surface of the third dielectric layer 383. The second via holes 392 may be filled to electrically couple one or more pads of the second metal layer 362 with one or more pads of the third metal layer 363. Similarly, third via holes 393 may be filled to electrically couple one or more pads of the fourth metal layer 364 with one or more pads of the fifth metal layer 365.

FIG. 3E illustrates a stage in which outer dielectric layer—the dielectric layer 240—may be formed (e.g., laminated) on an upper surface of the second dielectric layer 382. The dielectric layer 240 may also be referred to as first dielectric layer since it is the outermost dielectric layer in this instance. The dielectric layer 240 may cover the second metal layer 362.

In FIG. 3E, fourth dielectric layer 384 may also be formed on a lower surface of the third dielectric layer 383. The third dielectric layer 383 may cover the fifth metal layer 365. In this instance, the fourth dielectric layer 384 may be the outermost dielectric layer on a lower side of the core 370.

FIG. 3F illustrates a stage in which first via holes 391 and fourth via holes 394 may be formed within the (outer) dielectric layer 240 and the fourth dielectric layer 384, respectively. In an aspect, the first via holes 391 and/or the fourth via holes 394 may be formed through laser drilling. The first via holes 391 may expose one or more pads of the second metal layer 362, and the fourth via holes 394 may expose one or more pads of the fifth metal layer 365.

As seen in FIG. 3F, scribe lines 335 may also be formed within the dielectric layer 240. In an aspect, the scribe lines 335 may be formed through laser scribing process, which can be different from laser drilling process to form the via holes. The scribe lines 335 may correspond to shape and locations of the anchors 235. As such, laser scribing may form the scribe line 335 that penetrates the dielectric layer 240 to the depth below the upper surface of the dielectric layer 240 as described above with respect to the depth of the anchor 235.

FIG. 3G illustrates a stage in which conductive metal may be deposited and patterned to form first metal layer 361 (e.g., M1) and sixth metal layer 366 (e.g., M6) on the (first, outer) dielectric layer 240 and fourth dielectric layer 384, respectively. For example, the first metal layer 361 may be formed on an upper surface of the first dielectric layer 381, and the sixth metal layer 366 may be formed on a lower surface of the fourth dielectric layer 384. The first via holes 391 may be filled to electrically couple one or more pads of the first metal layer 361 with one or more pads of the second metal layer 362. Similarly, fourth via holes 394 may be filled to electrically couple one or more pads of the fifth metal layer 365 with one or more pads of the sixth metal layer 366.

As seen in FIG. 3G, the deposition and patterning to form the first metal layer 361 may also form the traces 230 along with corresponding anchors 235 that fill the scribe lines 335. As mentioned above, the presence of anchors 235 mitigates or prevents trace lifts from occurring. Also, design rules can be tightened as a result of the anchors 235.

FIG. 3H illustrates a stage in which SR 220 may be formed, e.g., on upper surface of the dielectric layer 240 and/or on lower surface of the fourth dielectric layer 384. The traces 230 within the trench open area may remain uncovered.

It is seen that in one or more aspects, the semiconductor package 200 may comprise one or more dielectric layers stacked on each other. The dielectric layer 240 with the traces 230 and corresponding anchors 235 may be the outer dielectric layer. It is also seen that the semiconductor package 200 may comprise one or more metal layers formed on upper surfaces of corresponding one or more dielectric layers 240, 382. In this instance, the one or more traces 230 may be parts of the first metal layer 361 formed on the upper surface of the dielectric layer 240.

The following should be noted. While the fabrication stages illustrated in FIG. 3A-3H shows dielectric layers and metal layers formed on both sides of the core, this is not a requirement. It is contemplated that the dielectric layers and the metal layers formed on one side of the core. Also, even if the dielectric and metal layers are formed on both sides, the number of layers need not be equal on both sides. Further, the anchors 235 and traces 230 may be formed on outer dielectric layers of one or both sides.

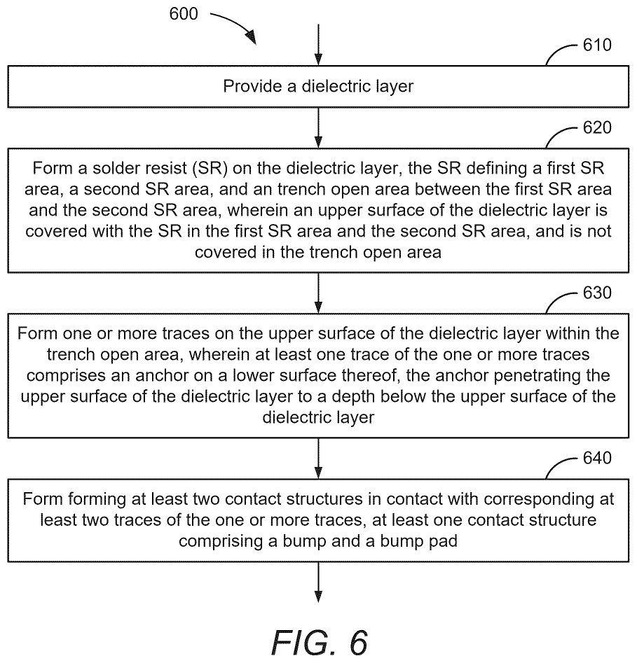

The scribe lines 335, and hence the anchors 235, can take on a variety of shapes. This is illustrated in FIG. 4A-4D. These are merely examples, and are not intended to limit the actual shapes that may be implemented.

FIG. 4A illustrates a solid line shape. In this shape, a single (relatively lengthy) line along a first length portion of the trace 230 may be formed. Relative to the width of the anchor 235, the first length portion may be many factor of times greater. FIG. 4B illustrates a dashed line shape. In this shape, one or more dashes along a second length portion of the trace 230 may be formed. Relative to the width of the anchor 235, length of each dash may be greater (but not as great as the solid line shape). Thus, there can be multiple dashes that can be formed. FIG. 4C illustrates dotted line shape. In this shape, one or more dots along a third length portion of the at least one trace. In this instance, relative to the width of the anchor 235, a length of a dot being less than or equal. FIG. 4D illustrates an example of a circumstance in which the shapes may be mixed.

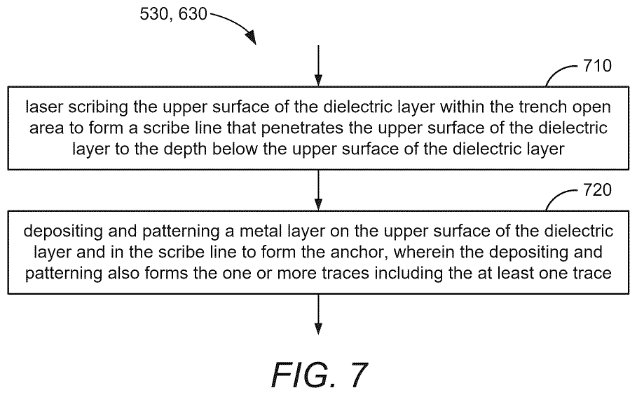

FIG. 5 illustrates a flow chart of an example method 500 of fabricating a semiconductor package, such as the semiconductor package 200, in accordance with at one or more aspects of the disclosure.

In block 510, dielectric layer 240 may be provided.

In block 520, solder resist (SR) 220 may be formed on the dielectric layer 240. The SR 220 may define a first SR area 212 and a second SR area 217. The SR 220 may also define a trench open area 215 between the first SR area 212 and the second SR area 217. Upper surface of the dielectric layer 240 may be covered with the SR 220 in the first SR area 212 and the second SR area 217. However, the SR 220 may not cover the trench open area 215.

In block 530, one or more traces 230 may be formed on the upper surface of the dielectric layer 240 within the trench open area 215. At least one trace 230 of the one or more traces 230 may comprise an anchor 235 on a lower surface thereof. The anchor 235 may penetrate the upper surface of the dielectric layer 240 to a depth below the upper surface of the dielectric layer 240.

FIG. 6 illustrates a flow chart of an example method 600 of fabricating a semiconductor package, such as the semiconductor package 200 in accordance with at one or more aspects of the disclosure. FIG. 6 may be viewed as being more comprehensive than FIG. 5.

Block 610 may be similar to block 510. That is, in block 610, dielectric layer 240 may be provided.

Block 620 may be similar to block 520. That is, in block 620, solder resist (SR) 220 may be formed on the dielectric layer 240. The SR 220 may define a first SR area 212 and a second SR area 217. The SR 220 may also define a trench open area 215 between the first SR area 212 and the second SR area 217. Upper surface of the dielectric layer 240 may be covered with the SR 220 in the first SR area 212 and the second SR area 217. However, the SR 220 may not cover the trench open area 215.

Block 630 may be similar to block 530. That is, in block 630, one or more traces 230 may be formed on the upper surface of the dielectric layer 240 within the trench open area 215. At least one trace 230 of the one or more traces 230 may comprise an anchor 235 on a lower surface thereof. The anchor 235 may penetrate the upper surface of the dielectric layer 240 to a depth below the upper surface of the dielectric layer 240.

In block 640, at least two contact structures 250 may be formed to be in contact with corresponding at least two traces 230 of the one or more traces 230. The at least one contact structure 250 comprising a bump 252 and a bump pad 255.

FIG. 7 illustrates a flow chart of an example process to perform block 530 of FIG. 5 (and hence block 630 of FIG. 6).

In block 710, the upper surface of the dielectric layer 240 within the trench open area 215 may be laser scribed to form the scribe line 335. The scribe line 335 may penetrate the upper surface of the dielectric layer 240 to the depth below the upper surface of the dielectric layer 240. Block 710 may correspond to FIG. 3F.

In block 720, a metal layer may be deposited and patterned on the upper surface of the dielectric layer 240 and in the scribe line 335 to form the anchor 235. The depositing and patterning may also form the one or more traces 230 including the at least one trace 230. Block 720 may correspond to the stage illustrated in FIG. 3G.

The following should be noted regarding the flow indicated in FIG. 5-7. Unless otherwise indicated, the flow of blocks do not necessarily limit the ordering in which the blocks may be performed. In other words, the blocks may be performed in any order that is logical.

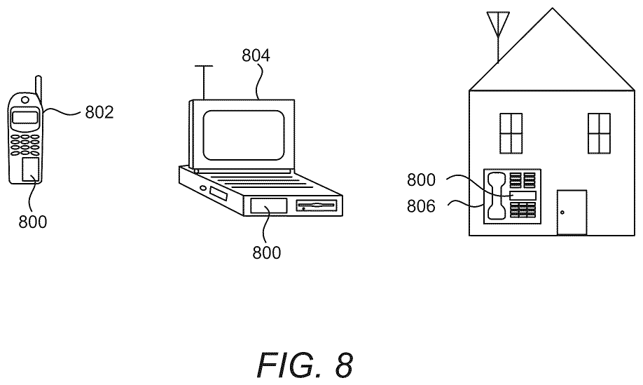

FIG. 8 illustrates various electronic devices 800 that may be integrated with any of the aforementioned semiconductor package in accordance with various aspects of the disclosure. For example, a mobile phone device 802, a laptop computer device 804, and a fixed location terminal device 806 may each be considered generally user equipment (UE) and may include one or more semiconductor packages (e.g., semiconductor package 200) as described herein. The devices 802, 804, 806 illustrated in FIG. 8 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A semiconductor package, comprising: a dielectric layer; a solder resist (SR) on the dielectric layer, the SR defining a first SR area, a second SR area, and a trench open area between the first SR area and the second SR area, wherein an upper surface of the dielectric layer is covered with the SR in the first SR area and the second SR area, and is not covered in the trench open area; and one or more traces on the upper surface of the dielectric layer within the trench open area, wherein at least one trace of the one or more traces comprises an anchor on a lower surface thereof, the anchor penetrating the upper surface of the dielectric layer to a depth below the upper surface of the dielectric layer.

Clause 2: The semiconductor package of clause 1, wherein the semiconductor package comprises one or more dielectric layers stacked on each other, and wherein the dielectric layer is an outer dielectric layer of the one or more dielectric layers.

Clause 3: The semiconductor package of clause 2, wherein the semiconductor package comprises one or more metal layers formed on upper surfaces of corresponding one or more dielectric layers, and wherein the one or more traces are parts of a first metal layer formed on the upper surface of the dielectric layer.

Clause 4: The semiconductor package of any of clauses 1-3, wherein the at least one trace and the anchor are integrally formed.

Clause 5: The semiconductor package of any of clauses 1-4, wherein a width of the at least one trace is less than or equal to 8 μm.

Clause 6: The semiconductor package of any of clauses 1-5, wherein a space between two adjacent traces of the one or more traces is less than or equal to 10 μm.

Clause 7: The semiconductor package of any of clauses 1-6, wherein the semiconductor package further comprises: at least two contact structures in contact with corresponding at least two traces of the one or more traces, at least one contact structure comprising a bump and a bump pad, wherein a pitch between the at least two contact structures is less than or equal to 54 μm.

Clause 8: The semiconductor package of any of clauses 1-7, wherein a width of the anchor is less than or equal to half of a width of the trace.

Clause 9: The semiconductor package of any of clauses 1-8, wherein the depth of penetration of the anchor into the dielectric layer is less than a height of the dielectric layer.

Clause 10: The semiconductor package of any of clauses 1-9, wherein the anchor of the at least one trace is shaped as any one or more of a solid line, a dashed line, or a dotted line, the solid line comprising a single line along a first length portion of the at least one trace, the dashed line comprising one or more dashes along a second length portion of the at least one trace, a length of a dash being greater than a width of the anchor, and the dotted line comprising one or more dots along a third length portion of the at least one trace, a length of a dot being less than or equal to the width of the anchor.

Clause 11: The semiconductor package of any of clauses 1-10, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 12: A method of fabricating a semiconductor package, the method comprising: providing a dielectric layer; forming a solder resist (SR) on the dielectric layer, the SR defining a first SR area, a second SR area, and a trench open area between the first SR area and the second SR area, wherein an upper surface of the dielectric layer is covered with the SR in the first SR area and the second SR area, and is not covered in the trench open area; and forming one or more traces on the upper surface of the dielectric layer within the trench open area, wherein at least one trace of the one or more traces comprises an anchor on a lower surface thereof, the anchor penetrating the upper surface of the dielectric layer to a depth below the upper surface of the dielectric layer.

Clause 13: The method of clause 12, wherein the semiconductor package comprises one or more dielectric layers stacked on each other, and wherein the dielectric layer is an outer dielectric layer of the one or more dielectric layers.

Clause 14: The method of clause 13, wherein the semiconductor package comprises one or more metal layers formed on upper surfaces of corresponding one or more dielectric layers, and wherein the one or more traces are parts of a first metal layer formed on the upper surface of the dielectric layer.

Clause 15: The method of any of clauses 12-14, wherein the at least one trace and the anchor are integrally formed.

Clause 16: The method of any of clauses 12-15, wherein a width of the at least one trace is less than or equal to 8 μm.

Clause 17: The method of any of clauses 12-16, wherein a space between two adjacent traces of the one or more traces is less than or equal to 10 μm.

Clause 18: The method of any of clauses 12-17, further comprising: forming at least two contact structures in contact with corresponding at least two traces of the one or more traces, at least one contact structure comprising a bump and a bump pad, wherein a pitch between the at least two contact structures is less than or equal to 54 μm.

Clause 19: The method of any of clauses 12-18, wherein a width of the anchor is less than or equal to half of a width of the trace.

Clause 20: The method of any of clauses 12-19, wherein the depth of penetration of the anchor into the dielectric layer is less than a height of the dielectric layer.

Clause 21: The method of any of clauses 12-21, wherein forming one or more traces on the upper surface of the dielectric layer within the trench open area comprise: laser scribing the upper surface of the dielectric layer within the trench open area to form a scribe line that penetrates the upper surface of the dielectric layer to the depth below the upper surface of the dielectric layer; and depositing and patterning a metal layer on the upper surface of the dielectric layer and in the scribe line to form the anchor, wherein the depositing and patterning also forms the one or more traces including the at least one trace.

Clause 22: The method of clause 21, wherein the scribe line is shaped as any one or more of a solid line, a dashed line, or a dotted line, the solid line comprising a single line along a first length portion of the at least one trace, the dashed line comprising one or more dashes along a second length portion of the at least one trace, a length of a dash being greater than a width of the anchor, and the dotted line comprising one or more dots along a third length portion of the at least one trace, a length of a dot being less than or equal to the width of the anchor.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor package, comprising:
a dielectric layer;
a solder resist (SR) on the dielectric layer, the SR defining a first SR area, a second SR area, and a trench open area between the first SR area and the second SR area, wherein an upper surface of the dielectric layer is covered with the SR in the first SR area and the second SR area, and is not covered in the trench open area; and
one or more traces on the upper surface of the dielectric layer within the trench open area, wherein at least one trace of the one or more traces comprises an anchor on a lower surface thereof, the anchor penetrating the upper surface of the dielectric layer to a depth below the upper surface of the dielectric layer.

2. The semiconductor package of claim 1,
wherein the semiconductor package comprises one or more dielectric layers stacked on each other, and
wherein the dielectric layer is an outer dielectric layer of the one or more dielectric layers.

3. The semiconductor package of claim 2,
wherein the semiconductor package comprises one or more metal layers formed on upper surfaces of corresponding one or more dielectric layers, and
wherein the one or more traces are parts of a first metal layer formed on the upper surface of the dielectric layer.

4. The semiconductor package of claim 1, wherein the at least one trace and the anchor are integrally formed.

5. The semiconductor package of claim 1, wherein a width of the at least one trace is less than or equal to 8 μm.

6. The semiconductor package of claim 1, wherein a space between two adjacent traces of the one or more traces is less than or equal to 10 μm.

7. The semiconductor package of claim 1, wherein the semiconductor package further comprises:
at least two contact structures in contact with corresponding at least two traces of the one or more traces, at least one contact structure comprising a bump and a bump pad, wherein a pitch between the at least two contact structures is less than or equal to 54 μm.

8. The semiconductor package of claim 1, wherein a width of the anchor is less than or equal to half of a width of the trace.

9. The semiconductor package of claim 1, wherein the depth of penetration of the anchor into the dielectric layer is less than a height of the dielectric layer.

10. The semiconductor package of claim 1, wherein the anchor of the at least one trace is shaped as any one or more of a solid line, a dashed line, or a dotted line,
the solid line comprising a single line along a first length portion of the at least one trace,
the dashed line comprising one or more dashes along a second length portion of the at least one trace, a length of a dash being greater than a width of the anchor, and
the dotted line comprising one or more dots along a third length portion of the at least one trace, a length of a dot being less than or equal to the width of the anchor.

11. The semiconductor package of claim 1, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

12. A method of fabricating a semiconductor package, the method comprising:
providing a dielectric layer;
forming a solder resist (SR) on the dielectric layer, the SR defining a first SR area, a second SR area, and a trench open area between the first SR area and the second SR area, wherein an upper surface of the dielectric layer is covered with the SR in the first SR area and the second SR area, and is not covered in the trench open area; and
forming one or more traces on the upper surface of the dielectric layer within the trench open area, wherein at least one trace of the one or more traces comprises an anchor on a lower surface thereof, the anchor penetrating the upper surface of the dielectric layer to a depth below the upper surface of the dielectric layer.

13. The method of claim 12,
wherein the semiconductor package comprises one or more dielectric layers stacked on each other, and
wherein the dielectric layer is an outer dielectric layer of the one or more dielectric layers.

14. The method of claim 13,
wherein the semiconductor package comprises one or more metal layers formed on upper surfaces of corresponding one or more dielectric layers, and
wherein the one or more traces are parts of a first metal layer formed on the upper surface of the dielectric layer.

15. The method of claim 12, wherein the at least one trace and the anchor are integrally formed.

16. The method of claim 12,
wherein a width of the at least one trace is less than or equal to 8 μm, or wherein a space between two adjacent traces of the one or more traces is less than or equal to 10 μm, or both.

17. The method of claim 12, further comprising:
forming at least two contact structures in contact with corresponding at least two traces of the one or more traces, at least one contact structure comprising a bump and a bump pad, wherein a pitch between the at least two contact structures is less than or equal to 54 μm.

18. The method of claim 12,
wherein a width of the anchor is less than or equal to half of a width of the trace, or
wherein the depth of penetration of the anchor into the dielectric layer is less than a height of the dielectric layer, or both.

19. The method of claim 12, wherein providing the dielectric layer and forming one or more traces on the upper surface of the dielectric layer within the trench open area comprise:
laser scribing the upper surface of the dielectric layer within the trench open area to form a scribe line that penetrates the upper surface of the dielectric layer to the depth below the upper surface of the dielectric layer; and
depositing and patterning a metal layer on the upper surface of the dielectric layer and in the scribe line to form the anchor, wherein the depositing and patterning also forms the one or more traces including the at least one trace.

20. The method of claim 19, wherein the scribe line is shaped as any one or more of a solid line, a dashed line, or a dotted line,
the solid line comprising a single line along a first length portion of the at least one trace,
the dashed line comprising one or more dashes along a second length portion of the at least one trace, a length of a dash being greater than a width of the anchor, and
the dotted line comprising one or more dots along a third length portion of the at least one trace, a length of a dot being less than or equal to the width of the anchor.
